(19) United States
(12) Patent Application Publication
(10) Pub. No.: US 2006/0227637 A1
(43) Pub. Date: Oct. 12, 2006

(54) Equalizer and method thereof and memory device

(76) Inventor: Cheng-Sheng Lee, Kaohsiung City (TW)

Correspondence Address: J C PATENTS, INC., 4 VENTURE, SUITE 250, IRVINE, CA, 92618, US

(21) Appl. No.: 11/188,041

(22) Filed: Jul. 22, 2005

(30) Foreign Application Priority Data
Apr. 6, 2005 (TW) 94110814

(51) Int. Cl. G11C 7/00

(52) U.S. Cl. 365/203

(57) ABSTRACT

An equalizer and a method thereof and a memory device are provided. The equalizer is used for the memory device having sense amplifier, first bit line and second bit line. The equalizer includes a first switch and a second switch. The first switch is coupled between a reference voltage and the first bit line for decision whether or not transmitting the reference voltage to the first bit line according to a first control signal. The second switch is coupled between the reference voltage and the second bit line for decision whether or not transmitting the reference voltage to the second bit line according to a second control signal. Wherein, the first control signal and the second control signal are difference.

### BACKGROUND OF THE INVENTION

1. Field of Invention

The present invention relates to a memory device, more specifically, to an equalizer, a method and a memory device with reduced noise.

2. Description of Related Art

DRAM is currently a most widely used memory. DRAM stores data using capacitors. Since the electric charge holding in capacitors may gradually drift away, therefore an additional periodic refresh process is required. FIG. 1 illustrates a diagram of the basic unit structure of the conventional DRAM. FIG. 2 describes the timing chart of the signals in FIG. 1. With reference to FIG. 1 and FIG. 2, in the standby states, the level of signals EQLt, EQLb, MUXt and MUXb is VINT, therefore the bit lines (BLL, /BLL, BLR and /BLR), the sense lines (SA and /SA) and the clock setting lines (NCS and PCS) are short-circuit with each other, and are pre-charged to the level of the reference voltage VBLEQ by the equalizers 130 and 140. Usually, the level of the reference voltage VBLEQ is set to half of the bit-line maximum level VBLH. When the memory cells array 110 of the left side of the FIG. 1 is enabled, the signals EQLt and MUXb are then transformed to VSS level. Then, in the memory cells array 110, the memory cells to be accessed are located through word-lines WLL (e.g. the word-line WLL0 in FIG. 1). In the signal developing stage, by opening the memory cell 112, the signals to be read are generated on the bit lines BLL, /BLL and sense lines SA, /SA (the bit-lines /BLL are floating at this time). Next, through the level state change of signals NCS and PCS, the sense amplifier 150 is activated. Therefore the signals of the sense lines SA, /SA (or the bit lines BLL, /BLL) are amplified correspondingly. As the level states of the word lines WLL (e.g. the word line WLL0 in FIG. 1) are transformed to VNN level and after the sense amplifier 150 is disabled, the signals EQLt, MUXt and MUXb are all returning to VINT level, and the bit lines BLL, /BLL, BLR, /BLR, sense lines SA, /SA, signal lines NCS and PCS are all pre-charged to the initial level VBLEQ.

As the core structure of the DRAM is getting smaller and smaller, the bit line interference problem is getting more and more serious. Being interfered with word lines, the un-neglectable coupling noise often occurs while sensing a bit line pair. Usually, a word line and 2048 bit line pairs form a coupling capacitance. Because of the coupling noise, the word line level will be reduced. Moreover, since usually a bit line and 512 word lines form a coupling capacitance, therefore the coupling noise will affect the bit line pairs. In other words, the bit line pairs have a feedback noise (from a bit line to another bit line via a word line). If the pre-charge state of the word line is VSS, since the common sources point (NCS) of the N-channel sense amplifier is also VSS, therefore the noise can be eliminated. But in the progressing DRAM design, the pre-charge state of the word line is VNN (negative voltage), but not VSS, such noise will reduce (increase) the actual VBLEQ level of the word line sensing point. For example, the coupling noise C-NOISE in FIG. 2 reduces the bit line /BLL's level.

### SUMMARY OF THE INVENTION

An object of the present invention is to provide an equalizer to avoid the level being affected by other circuit coupling noise caused by bit-line floating.

Another object of the present invention is to provide an equalizing method to eliminate the coupling noise of the bit lines in the memory device.

Another object of the present invention is to provide a memory device which avoids a level of the bit-line pair being affected by the coupling noise when sensing the bit-line pair signals.

From another point of view, the present invention provides an equalizing method used in a memory device which at least includes a first bit line, a second bit line, a sense amplifier and the memory cells coupled to the first bit line. Wherein, the sense amplifier is coupled to the first bit line and the second bit line. Such equalizing method includes flowing steps. The first-bit line and the second bit-line are charged to the reference voltage when the memory cell is off. The first bit-line stops in charging and the second bit-line is continuously charged to maintain the level at the reference voltage when the memory cell is opened or before the memory cell is opened. The second bit-line stops in charging when the sense amplifier is activated or before the sense amplifier is activated.

Since the present invention uses a plurality of control signals of different time sequences to control the equalizer after the bit lines have been pre-charged by equalizer and when the bit lines are just to be sensed. This avoids the occurrence of bit-line floating, and therefore the bit-line coupling noise in the memory device can be eliminated.

These and other exemplary embodiments, features, aspects, and advantages of the present invention will be described and become more apparent from the detailed description of exemplary embodiments when read in conjunction with accompanying drawings.

### BRIEF DESCRIPTION OF THE DRAWINGS

FIG. 1 illustrates the diagram of the basic unit structure of the conventional DRAM.

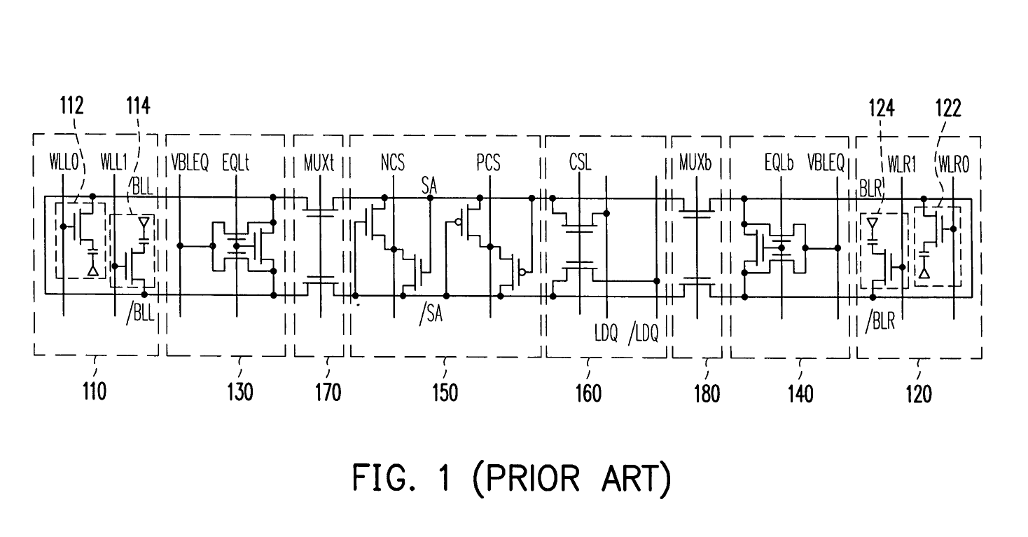

FIG. 2 describes the timing chart of the signals in FIG. 1.

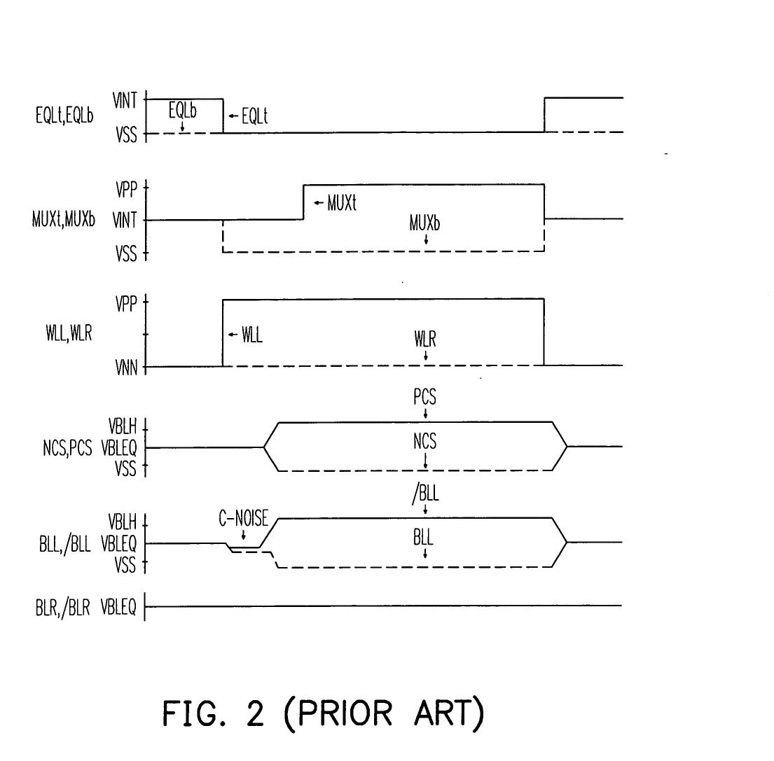

FIG. 3 describes an embodiment of a memory device according to the present invention.

FIG. 4 describes the timing chart of the signals in FIG. 3 according to the embodiment of the present invention.

### DESCRIPTION OF THE PREFERRED EMBODIMENTS

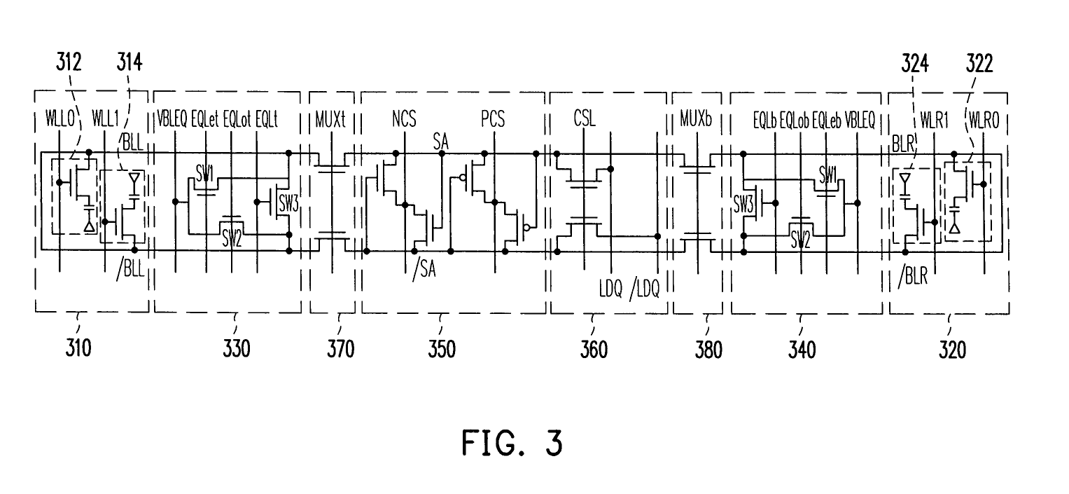

To describe conveniently, now the dynamic random access memory (DRAM) is taken as an example to exemplify the embodiments of the present invention. FIG. 3 describes an embodiment of a memory device according to the present invention. With reference FIG. 3, the present embodiment can eliminate noise on the bit line and the word line, and can make the bit line to maintain the reference voltage level of pre-charge during the signal developing period. The DRAM has memory cells arrays 310, 320, the equalizers 330, 340, the column switch 360 and the sense amplifier 350. Herein, the memory cell array 310 is represented by the memory cell 312 coupled to word-line WLL0 and the memory cell 314 coupled to word-line WLL1. The memory cell array 320 is represented merely by the memory cell 322 coupled to word-line WLR0 and the memory cell 324 coupled to word-line WLR1. Wherein, whether the logic state of the DRAM being 1 or 0 is determined by whether the capacitor holding electric charge or not.

The sense amplifier 350 and the column switch 360 are shared by the left side and right side memory cell arrays 310 and 320, therefore the switch 370 and 380 are located to determine which one can use the sense amplifier 350 and the column switch 360. In other words, the sense amplifier 350 can be coupled to the first bit line BLL and the second bit line /BLL of the memory cell array 310 via switch 370, or can be coupled to the first bit line BLR and the second bit line /BLR of the memory cell array 320 via the switch 380.

Each of the memory cell arrays is implemented with a bit-line equalizer. For example, the equalizers 330 and 340 are respectively implemented in the memory cell arrays 310, 320. Herein, only the equalizing device 330 is taken as an example in the description. The equalizer 330 includes a first switch SW1, a second switch SW2 and a third switch SW3. The switch SW1 is coupled between the reference voltage VBLEQ and the first bit-line BLL to determine whether or not the reference voltage VBLEQ is transmitted to the first bit-line BBL according to the first control signal EQLet. The switch SW2 is coupled between the reference voltage VBLEQ and the second bit-line /BLL to determine whether or not the reference voltage VBLEQ is transmitted to the second bit-line /BLL according to the second control signal EQLot. The switch SW3 is coupled between the first bit-line BLL and the second bit-line /BLL to determine whether or not a short-circuit is between the first bit-line BLL and the second bit-line /BLL according to the first control signal EQLt.

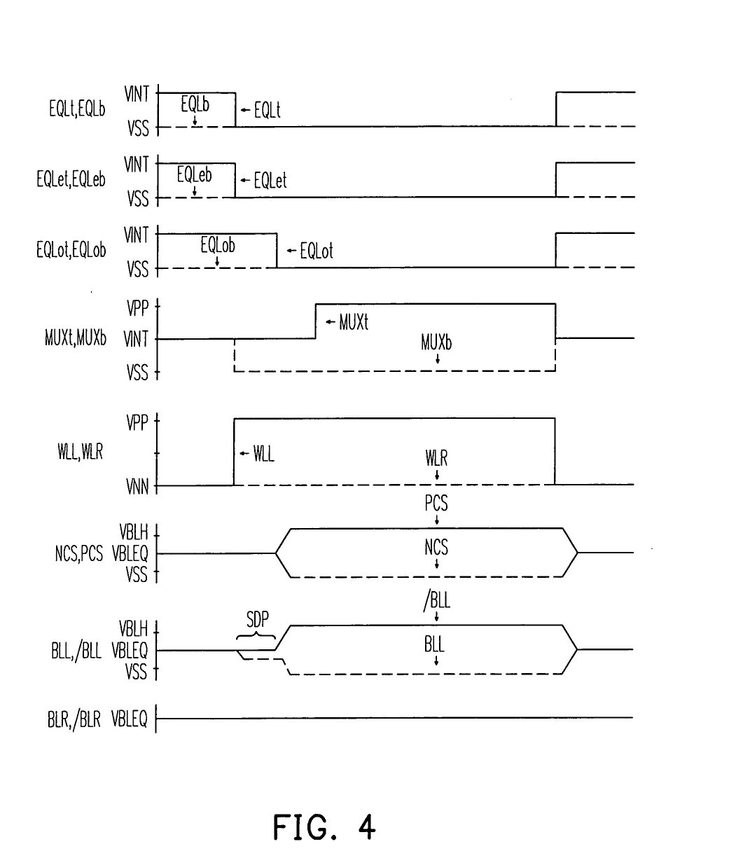

FIG. 4 describes the timing chart of the signals in FIG. 3 according to the embodiment of the present invention. With reference to FIG. 3 and FIG. 4, when the memory cells 312 and 314 are closed (standby state), the level of the signals EQLt-EQLet-EQLot-EQLb-EQLeb-EQLob-MUXt and MUXb is VINT. Therefore the bit lines (BLL-/BLL-BLR and /BLR), the sense lines (SA and /SA) and the clock-setting lines (NCS and PCS) are in short-circuit with each other, and they are pre-charged to the reference voltage VBLEQ level through the equalizers 330 and 340 (e.g. closing the circuit of the first switch SW1, second switch SW2 and the third switch SW3 in the equalizer). Here, the level of the reference voltage VBLEQ can be set as a half of the bit-line's highest level VBLH.

When the left side memory cell array 310 in FIG. 3 is enabled, for example when the memory cell 312 is opened (or before the memory cell 312 is opened) through the bit-line WLL0, the signals EQLt-EQLet and MUXb are then transformed to the VSS level, so that the switches SW1, SW3 and 380 form an open circuit. Now the switch SW2 is still in a conduction state. Then the first bit-line BLL is coupled with the capacitor of the memory cell 312 for holding electric charge. Now the level of the signal to be read is formed in the bit-line BLL and sense-line SA. Comparing with the conventional technology, since in the present embodiment, the switch SW2 is maintained in a conducting circuit state through the second control signal EQLot (as shown in FIG. 4) during the signal developing period (SDP), i.e. the second bit-line /BLL is kept on being charged during the signal developing period (SDP), so that its level maintains at the reference voltage VBLEQ. Therefore, this avoids the occurrence of the bit-lines (BLL and /BLL) and the sense-lines (SA and /SA) being in floating state, and consequently avoids the level being affected by the coupling noise of other circuits.

Then, the sense amplifier 350 is activated through the state change of the signals NCS and PCS. When the sense amplifier 350 is activated or before sense amplifier 350 is activate, the second switch SW2 is set to be off state by use of the second control signal EQLot. At this time, the signals of the sense line pair SA, /SA (or the bit-line pair BLL, /BLL) are then amplified correspondingly. As a level of the word line WLL (e.g. the word line WLL0 in FIG. 3) is transformed to the VNN level, and after the sense amplifier 350 is disabled, signals EQLt, EQLet, EQLot, MUXt and MUXb are all returning to VINT, and the bit lines BLL, /BLL, BLR, /BLR, the sense line SA, /SA, the signal lines NCS and PCS are all pre-charged to the reference voltage VBLEQ, so as to be ready for the next access.

The above embodiment takes the access to the even number word-line memory cells (for example the memory cell 312 coupled to the word line WLL0) as an example. Similarly, to access to the odd number word-line memory cells (for example the memory cell 314 coupled to the word line WLL1), it can be done by just delaying the first control signal EQLet instead of delaying the second control signal EQLot. That is, when the memory cell 314 is on (or before the memory cell 314 is on), signals EQLt and EQLot are then transformed to VSS level, so that the switches SW2 and SW3 form an open circuit. At this time, the switch SW1 still maintains a conducting circuit state, thus it can prevent the bit lines BLL and /BLL, the sense lines SA and /SA from being floating, and therefore the level can be avoided from being affected by the coupling noise of other circuits.

Wherein, those who are skilled in the ordinary art can set the timing of the first control signal EQLt, the second control signal EQLet and the third control signal EQLot according to the actual need. For example, the time sequences of the first control signal EQLt, the second control signal EQLet and the third control signal EQLot can be set in different timing from each other.

To sum up, since the present invention uses the equalizer to complete the pre-charge of the bit-line pair. Then, just before sensing the bit-line pair, a plurality of control signals in different timing is used to control the equalizer, this avoids the occurrence of bit-line floating, and therefore the bit-line coupling noise in the memory device can be eliminated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An equalizer, used in a memory device which at least comprises a sense amplifier, a first bit line and a second bit line, wherein the sense amplifier is coupled with the first bit line and the second bit line, the equalizer comprising:
a first switch, coupled between a reference voltage and the first bit line to determine whether or not transmitting the reference voltage to the first bit-line according to a first control signal; and
a second switch, coupled between the reference voltage and the second bit line to determine whether or not transmitting the reference voltage to the second bit line according to a second control signal.

2. The equalizer of the claim 1, further comprising:
a third switch, coupled between the first bit line and the second bit line to determine whether or not a short-circuit is between the first bit-line and the second bit line according to a third control signal.

3. The equalizer of the claim 2, wherein the memory device further comprises at least a memory cell coupled to the first bit line and a word line coupled to the memory cell, wherein the first switch, the second switch and the third switch are conducted when the memory cell is off, the first switch and the third switch are set to an open circuit by the first control signal and the third control signal respectively when the memory cell is turned on by the word line or before the memory cell is turned on, and the second switch is maintained in conducting by the second control signal.

4. The equalizer of claim 3, wherein the second switch is set to open circuit by the second control signal when the sense amplifier is activated or just before the sense amplifier is activated.

5. The equalizer of claim 1, wherein the memory device is a dynamic random access memory (DRAM).

6. An equalizing method, used in a memory device which at least comprising a first bit line, a second bit line, a sense amplifier and a memory cell coupled to the first bit line, wherein the sense amplifier is coupled to the first bit line and the second bit line, the equalizing method comprising:
charging the first bit line and the second bit line to a reference voltage while the memory cell is off;
stopping charging the first bit line and continuing charging the second bit line so that the second bit line maintains at the reference voltage level when the memory cell is on or just before the memory is opened; and
stopping charging the second bit line when the sense amplifier is activated or just before the sense amplifier is activated.

7. The equalizing method of claim 6, wherein the memory device is a dynamic random access memory (DRAM).

8. A memory device, comprising:
a first bit line;
a second bit line;
a word line;
a sense amplifier, coupled to the first bit line and the second bit line;
at least a memory cell, coupled to the first bit line and the word line; and
a equalizer, comprising:
a first switch, coupled between a reference voltage and the first bit line to determine whether or not transmitting the reference voltage to the first bit line according to a first control signal; and
a second switch, coupled between the reference voltage and the second bit line to determine whether or not transmitting the reference voltage to the second bit line according to a second control signal.

9. The memory device of claim 8, wherein the equalizer further comprises: a third switch, coupled between the first bit line and the second bit line to determine whether or not a short-circuit is between the first bit line and the second bit line according to a third control signal.

10. The memory device of claim 9, wherein the first switch, the second switch and the third switch are conducted when the memory cell is off, the first switch and the third switch circuit are opened by the first control signal and the third control signal respectively when the memory cell is turned on by the word line or just before the memory cell is turned, and the second switch is maintained conducting by the second control signal.

11. The memory device of claim 10, wherein the second switch circuit is opened by the second control signal when the sense amplifier is activated or just before the sense amplifier is started.

12. The memory device of claim 8, wherein the memory device is a dynamic random access memory (DRAM).
